(19) United States
(12) Patent Application Publication
(10) Pub. No.: US 2012/0142129 A1
(43) Pub. Date: Jun. 7, 2012

(54) METHOD OF MANUFACTURING SEMICONDUCTOR LASER HAVING DIFFRACTION GRATING

(75) Inventor: Yukihiro TSUJI, Yokohama-shi (JP)

(73) Assignee: SUMITOMO ELECTRIC INDUSTRIES, LTD., Osaka (JP)

(21) Appl. No.: 13/304,724

(22) Filed: Nov. 28, 2011

(30) Foreign Application Priority Data
Dec. 1, 2010 (JP) 2010-268515

(51) Int. Cl. H01L 21/30

(52) U.S. Cl. 438/32; 257/E21.211

(57) ABSTRACT

A method of manufacturing a semiconductor laser having a diffraction grating includes the steps of forming a first semiconductor layer on a semiconductor substrate; forming periodic projections and recesses which constitute a diffraction grating in the first semiconductor layer; cleaning a surface of the first semiconductor layer with water; drying the surface of the first semiconductor layer; and forming a second semiconductor layer on the first semiconductor layer. In drying the surface of the first semiconductor layer, after replacing water adhering to the surface of the first semiconductor layer with a water-soluble organic solvent, exposing the surface of the first semiconductor layer provided with the projections and recesses to an atmosphere containing the water-soluble organic solvent. At least one of the first semiconductor layer and the second semiconductor layer is composed of a p-type semiconductor.

### BACKGROUND OF THE INVENTION

1. Field of the Invention

The present invention relates to a method of manufacturing a semiconductor laser having a diffraction grating.

2. Description of the Related Art

Patent Document 1 (Japanese Unexamined Patent Application Publication No. 2008-300737) discloses a method of manufacturing a distributed feedback (DFB) laser. In the method of manufacturing the semiconductor laser, after a grating layer having a diffraction grating is formed by etching, semiconductor layers are formed on the grating layer.

### SUMMARY OF THE INVENTION

In a process of manufacturing a distributed feedback (DFB) laser, a high-resistivity layer may be formed at the interface between epitaxially grown layers in some cases. Increasing series resistance due to the high-resistivity layer influences laser characteristics such as high modulation characteristics. Especially, when the semiconductor laser is directly modulated at a high modulation rate of 10 Gbps or more, the high-frequency characteristics of the semiconductor laser is remarkably degraded by having the high-resistivity layer.

A method of manufacturing a semiconductor laser having a diffraction grating according to the present invention includes the steps of forming a first semiconductor layer on a semiconductor substrate; forming periodic projections and recesses which constitute a diffraction grating in the first semiconductor layer; cleaning a surface of the first semiconductor layer provided with the projections and recesses with water; drying the surface of the first semiconductor layer provided with the projections and recesses; and forming a second semiconductor layer on the first semiconductor layer provided with the projections and recesses. Furthermore, in the step of drying the surface of the first semiconductor layer provided with the projections and recesses, after replacing water adhering to the surface of the first semiconductor layer with a water-soluble organic solvent, the surface of the first semiconductor layer provided with the projections and recesses is exposed in an atmosphere containing the water-soluble organic solvent. In addition, at least one of the first semiconductor layer and the second semiconductor layer is composed of a p-type semiconductor.

According to this method, in the step of drying the surface of the first semiconductor layer provided with the projections and recesses after the step of cleaning a surface of the first semiconductor layer provided with the projections and recesses with water, water adhering to the surface of the first semiconductor layer is replaced with a water-soluble organic solvent. Then, the surface of the first semiconductor layer provided with the projections and recesses is exposed in an atmosphere containing the water-soluble organic solvent. As a result, it is possible to decrease the concentration of silicon remaining on the surface of the first semiconductor layer having a diffraction grating. Thereby, even when at least one of the first semiconductor layer and the second semiconductor layer is composed of a p-type semiconductor, the series resistance of the semiconductor laser having a diffraction grating can be decreased. Consequently, it is possible to manufacture a semiconductor laser provided with a diffraction grating having good modulation characteristics.

Furthermore, preferably, in the step of drying the surface of the first semiconductor layer provided with the projections and recesses, in replacing water adhering to the surface of the first semiconductor layer with the water-soluble organic solvent, the semiconductor substrate is immersed in the water-soluble organic solvent at room temperature after the step of cleaning the surface of the first semiconductor layer with water. Furthermore, in exposing the surface of the first semiconductor layer provided with the projections and recesses in an atmosphere containing the water-soluble organic solvent, the atmosphere containing the water-soluble organic solvent is generated by heating the water-soluble organic solvent to a temperature equal to or higher than the boiling point of the water-soluble organic solvent.

Furthermore, preferably, the semiconductor substrate is composed of an n-type semiconductor. In this case, in a structure of a semiconductor laser including a semiconductor substrate composed of an n-type semiconductor, a first semiconductor layer composed of a p-type semiconductor disposed on the semiconductor substrate, and a second semiconductor layer composed of a p-type semiconductor disposed on the first semiconductor layer, the first semiconductor layer and the second semiconductor layer are each composed of a p-type semiconductor. Therefore, the manufacturing method according to the present invention can be suitably applied thereto.

Furthermore, the first semiconductor layer and the second semiconductor layer may be composed of different semiconductors, and the band gap energy of the first semiconductor layer may be different from the band gap energy of the second semiconductor layer. Furthermore, in the step of forming the second semiconductor layer on the first semiconductor layer, a heterojunction may be formed at the interface between the first semiconductor layer and the second semiconductor layer. According to this method, when a heterojunction is formed at the interface between the first semiconductor layer and the second semiconductor layer, by decreasing the concentration of silicon remaining on the surface of the first semiconductor layer having a diffraction grating, the series resistance of the semiconductor laser having a diffraction grating can be effectively decreased. Consequently, it is possible to manufacture a semiconductor laser provided with a diffraction grating having good modulation characteristics.

Furthermore, preferably, the water-soluble organic solvent is at least one of isopropyl alcohol, methanol, and ethanol. Isopropyl alcohol, methanol, and ethanol have high volatility and can be quickly dried off.

Furthermore, the first semiconductor layer may be composed of p-type GaInAsP, and the second semiconductor layer may be composed of p-type InP.

### BRIEF DESCRIPTION OF THE DRAWINGS

FIG. 1 is a flow chart showing a method of manufacturing a semiconductor laser having a diffraction grating;

FIG. 2A is a cross-sectional perspective view showing a step of forming a plurality of semiconductor layers, and FIG. 2B is a cross-sectional perspective view showing a step of forming a stripe-shaped mesa including active layer;

FIG. 3A is a cross-sectional perspective view showing a step of re-growing semiconductor layers, and FIG. 3B is a cross-sectional perspective view showing a step of forming a p-side electrode;

FIG. 4 is a flow chart showing a method of manufacturing a semiconductor laser having a diffraction grating according to a comparative example;

FIG. 5 is a flow chart showing a method of manufacturing a semiconductor laser having a diffraction grating according to an embodiment;

FIG. 6A is a cross-sectional view showing a step in a method of manufacturing a semiconductor laser having a diffraction grating, and FIG. 6B is a cross-sectional view showing a step subsequent to the step of FIG. 6A;

FIG. 7A is a cross-sectional view showing a step subsequent to the step of FIG. 6B, and FIG. 7B is a cross-sectional view showing a step subsequent to the step of FIG. 7A;

FIG. 8A is a cross-sectional view showing a step subsequent to the step of FIG. 7B, and FIG. 8B is a cross-sectional view showing a step subsequent to the step of FIG. 8A;

FIG. 9A is a cross-sectional view showing a step in a method of manufacturing a semiconductor laser having a diffraction grating according to an embodiment, and FIG. 9B is a cross-sectional view showing a step subsequent to the step of FIG. 9A;

FIG. 10A is a cross-sectional view showing a step subsequent to the step of FIG. 9B, and FIG. 10B is a cross-sectional view showing a step subsequent to the step of FIG. 10A;

FIGS. 11A and 11B are cross-sectional views showing the reason why silicon contained in ultrapure water remains on the surface of a grating layer provided with projections and recesses;

FIG. 12 is a cross-sectional view showing the position at which the silicon concentration was measured inside a semiconductor laser having a diffraction grating;

FIG. 13 is a graph showing the silicon concentration inside a semiconductor laser having a diffraction grating;

FIG. 14 is a graph showing the silicon concentration at the regrowth interfaces of semiconductor lasers having a diffraction grating; and

FIG. 15A is a graph showing the laser oscillation threshold of a semiconductor laser produced by a method of manufacturing a semiconductor laser having a diffraction grating according to a comparative example, and FIG. 15B is a graph showing the laser oscillation threshold of a semiconductor laser produced by a method of manufacturing a semiconductor laser having a diffraction grating according to an embodiment.

### DESCRIPTION OF THE PREFERRED EMBODIMENTS

A method of manufacturing a semiconductor laser having a diffraction grating according to the present invention will be described in detail below with reference to the accompanying drawings. In the drawings, the same components are designated by the same reference numerals, and duplicate descriptions are omitted.

Examples of a semiconductor laser having a diffraction grating include a distributed feedback (DFB) laser and a distributed Bragg reflector (DBR) laser. In a DFB laser, a diffraction grating is formed over the entire region of the active layer. On the other hand, in a DBR semiconductor laser, a diffraction grating is formed in a different region from that of the active layer. In this embodiment, a method of manufacturing a DFB laser will be described.

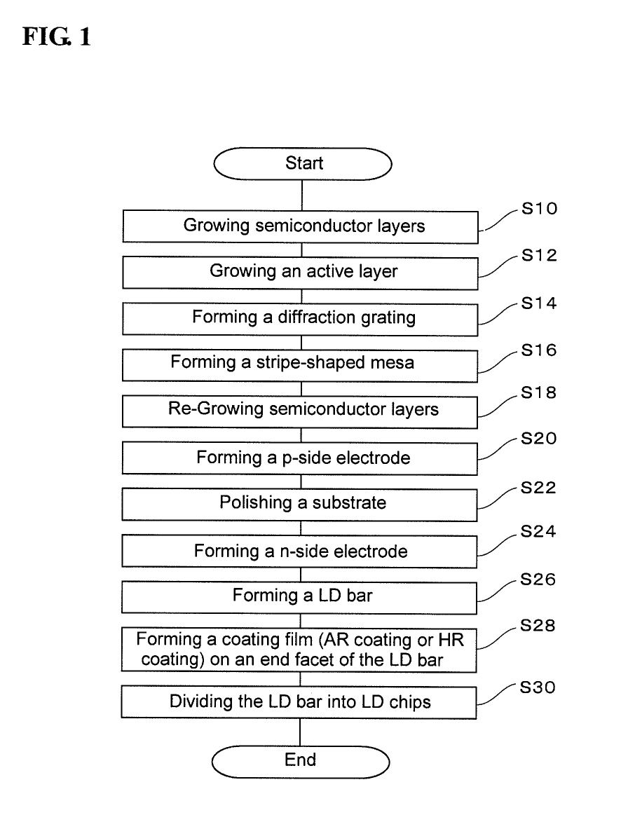

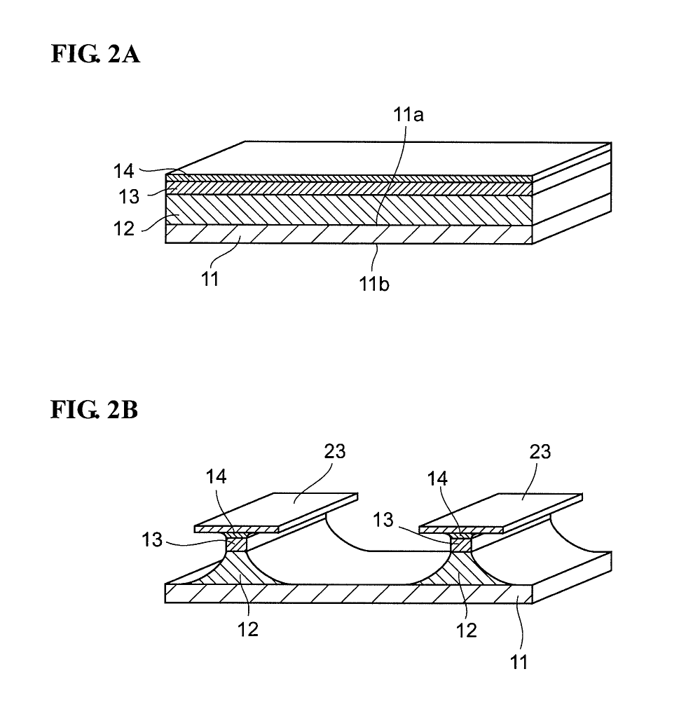

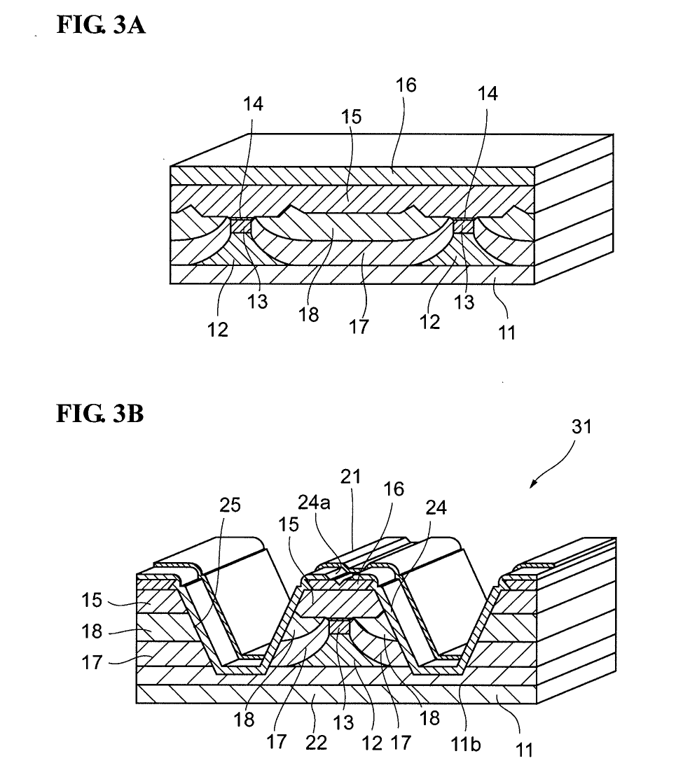

First, a method of manufacturing a DFB laser will be described with reference to FIGS. 1 to 3B. FIG. 1 is a flow chart showing a method of manufacturing a DFB laser. FIGS. 2A to 3B are each a perspective view showing a cross-section of a substrate product produced by a process of the method of manufacturing a DFB laser. In this manufacturing method, the individual semiconductor layers constituting the DFB laser are grown on a substrate by an epitaxial growth method such as a metalorganic chemical vapor deposition (MOCVD) method, a molecular beam epitaxy (MBE) method, or the like.

As shown in FIG. 2A, a semiconductor substrate 11 on which a plurality of semiconductor layers are to be grown is prepared. The semiconductor substrate 11 has a principal surface 11a and a principal surface 11b opposed to the principal surface 11a. As the semiconductor substrate 11, for example, an n-type InP substrate doped with silicon is used. After the semiconductor substrate 11 is loaded in a growth chamber, a first cladding layer 12 is formed on the principal surface 11a of the semiconductor substrate 11 (S10). The first cladding layer 12 is, for example, composed of n-type InP. Next, an active layer 13 is formed on the first cladding layer 12 (S12). The active layer 13 has a multiple quantum well (MQW) structure in which a plurality of well layers and the barrier layers are alternately stacked. For example, the well layer and barrier layer constituting the MQW structure are composed of AlGaInAs or GaInAsP with different compositions.

Next, a grating layer (first semiconductor layer) 14 is formed on the active layer 13 (S14). The grating layer 14 is, for example, composed of p-type InGaAsP. An insulating film (not shown) having a diffraction grating pattern is formed on the grating layer 14, and the grating layer 14 is etched using the insulating film as a mask. The insulating film is composed of, for example, silicon nitride (SiN) or silicon oxide (SiO₂). As a result, a diffraction grating having periodic projections and recesses is formed in the grating layer 14. Next, part of a second cladding layer 15 composed of p-type InP and a cap layer composed of p-type InGaAs are formed on the grating layer 14 (not shown). The second cladding layer 15 is formed so as to embed the projections and recesses formed in the grating layer 14.

Next, as shown in FIG. 2B, a mask 23 is formed on the grating layer 14 (on the p-type InGaAs cap layer in this embodiment). As the mask 23, for example, a silicon nitride (SiN) film is used. Then, by etching the semiconductor layers including the first cladding layer 12, the active layer 13, the grating layer 14, the second cladding layer 15, and the cap layer by using the mask 23, a stripe-shaped mesa is formed (S16). Next, as shown in FIG. 3A, by using the mask 23 as a selective growth mask, a first buried layer 17 and a second buried layer 18 are formed on side faces of the stripe-shaped mesa. Next, the mask 23 and the cap layer are removed by etching to expose the surface of the second cladding layer 15 composed of p-type InP, and then a remaining portion of the second cladding layer 15 and a contact layer 16 composed of p-type InGaAs are formed on the surface of the second cladding layer 15 and on the surface of the second buried layer 18 (S18). The first buried layer 17 is, for example, composed of p-type InP, and the second buried layer 18 is, for example, composed of n-type InP. Note that an interface formed by the grating layer 14 and the second cladding layer 15 formed thereon is referred to as a “regrowth interface”.

Next, as shown in FIG. 3B, trenches 25 are formed at both sides of the stripe-shaped mesa including the active layer 13. Then, an insulating film 24 is formed on the contact layer 16 and on the inside of the trenches 25. An opening 24a is formed in the insulating film 24 to expose the contact layer 16. The opening 24a can be formed by, for example, using dry etching. As the insulating film 24, for example, a silicon nitride (SiN) film or a silicon oxide (SiO₂) film may be used. Then, a p-side electrode 21 is formed on the insulating film 24 and the contact layer 16 (S20). The p-side electrode 21 is electrically connected to the contact layer 16 through the opening 24a. Next, after polishing the other principal surface 11b (back surface) opposed to the principal surface 11a of the semiconductor substrate 11 (S22), an n-side electrode 22 is formed on the principal surface 11b (S24).

Next, the substrate product 31 produced by the steps described above is divided into semiconductor laser bars (LD bars) (S26). In each LD bar, a plurality of DFB lasers are arranged in line. Next, each end facet of the divided LD bars is coated with either a high reflection (HR) film or a low reflection (AR) film (S28). Then, the LD bar is divided into individual semiconductor laser chips (LD chips) (S30). A DFB laser is manufactured by undergoing the steps described above.

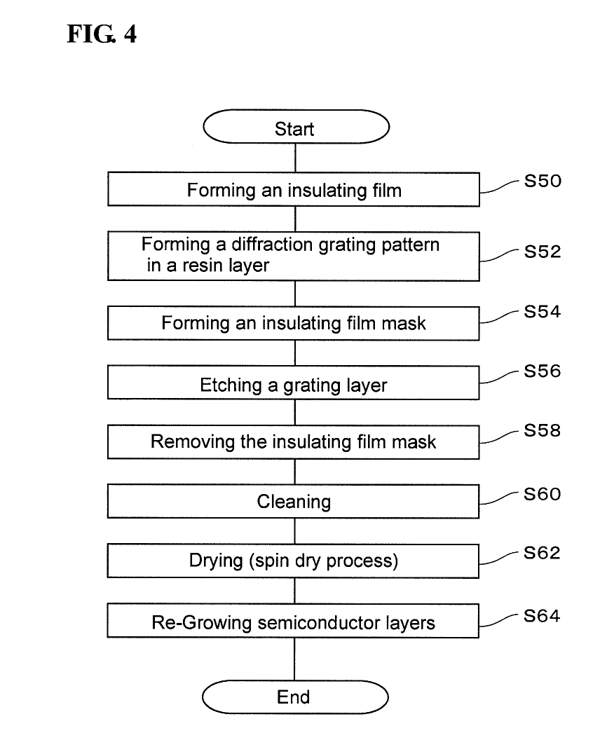

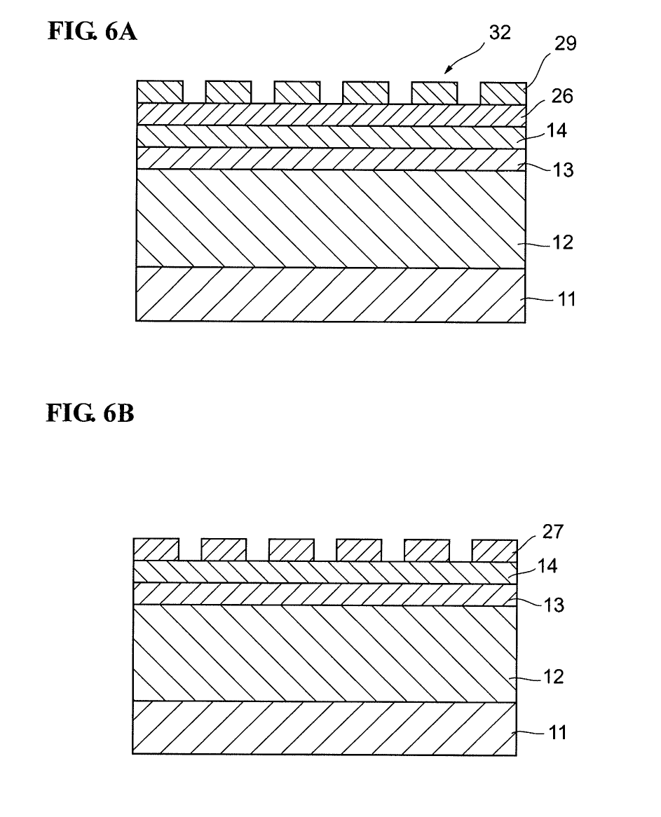

Next, a method of manufacturing a DFB laser including a process of cleaning a diffraction grating according to a comparative example will be described in detail with reference to FIGS. 4 and 6A to 8B. FIG. 4 is a flow chart showing a method of manufacturing a semiconductor laser according to the comparative example. FIGS. 6A to 8B are each a cross-sectional side view showing a substrate product produced by a process of the method of manufacturing a DFB laser. FIGS. 4 and 6A to 8B describe in detail the step of forming a diffraction grating (S14) shown in FIG. 1.

As shown in FIG. 6A, an insulating film 26 is formed on a grating layer 14 in a substrate product 32 in which a plurality of semiconductor layers have been formed (S50). As the insulating film 26, for example, a silicon oxide (SiO₂) film is used. A resin (resist) layer is applied onto the insulating film 26. Then, a diffraction grating pattern having a predetermined grating period is formed in the resin layer by using, for example, electron beam (EB) lithography. Then, a resin pattern 29 having periodic projections and recesses is formed (S52).

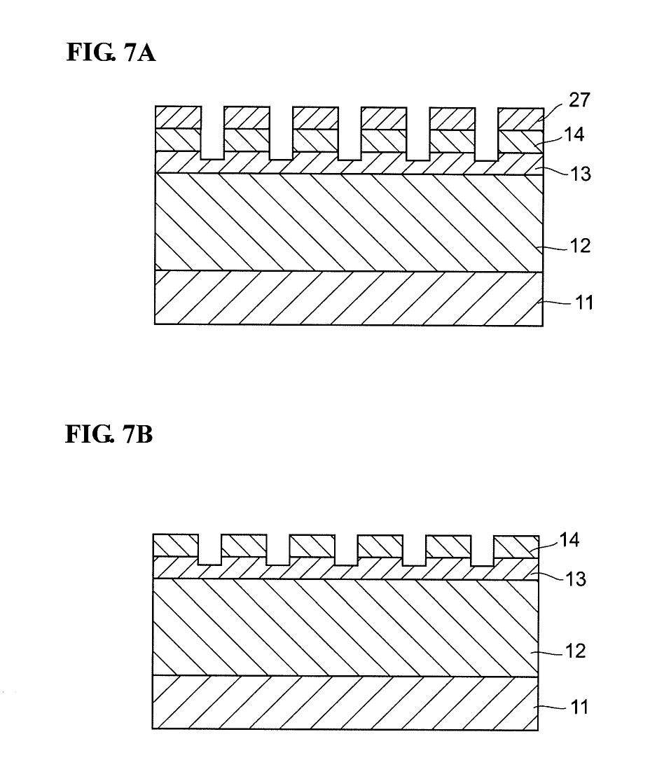

Next, by using the resin pattern 29 having the diffraction grating pattern, the insulating film 26 is etched to transfer the diffraction grating pattern to the insulating film 26. In this etching, for example, reactive ion etching (RIE) can be used. Next, O2 ashing is performed to remove the resin pattern 29. When the resin pattern 29 is removed, as shown in FIG. 6B, an insulating film mask 27 for forming a diffraction grating is formed (S54). Subsequently, as shown in FIG. 7A, by using the insulating film mask 27 having the diffraction grating pattern, the grating layer 14 is etched (S56). In this etching, a wet etching process or dry etching process is used. As the dry etching, for example, reactive ion etching can be used. Next, the insulating film mask 27 is removed (S58). In the process of removing the insulating film mask 27, for example, hydrofluoric acid is used. Furthermore, etching (wet etching) is performed in order to remove a layer damaged by reactive ion etching (S58). When the insulating film mask 27 and the damaged layer are removed, as shown in FIG. 7B, a diffraction grating having periodic projections and recesses is formed in a grating layer 14.

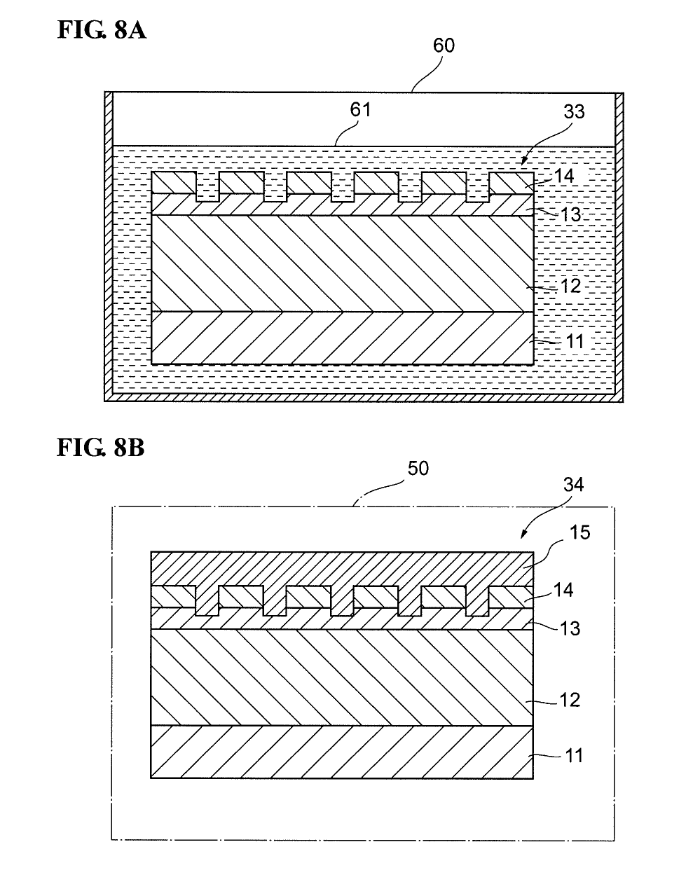

Next, as shown in FIG. 8A, in order to clean off extraneous matter including hydrofluoric acid and the like adhering to the grating layer 14 provided with the diffraction grating, a substrate product 33 is placed in a cleaning apparatus 60 and then, the substrate product 33 is cleaned (S60). In the cleaning process, ultrapure water 61 is used as a cleaning liquid. After cleaning, a spin dry process is performed (S62). Then, as shown in FIG. 8B, a substrate product 34 is immediately loaded into a growth chamber 50, and a step (re-growth step) of growing part of a second cladding layer 15 on the grating layer 14 is carried out (S64).

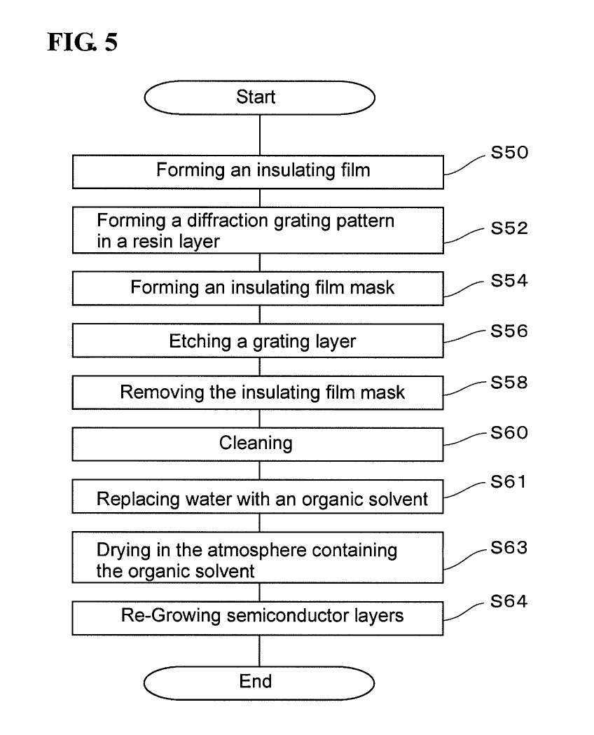

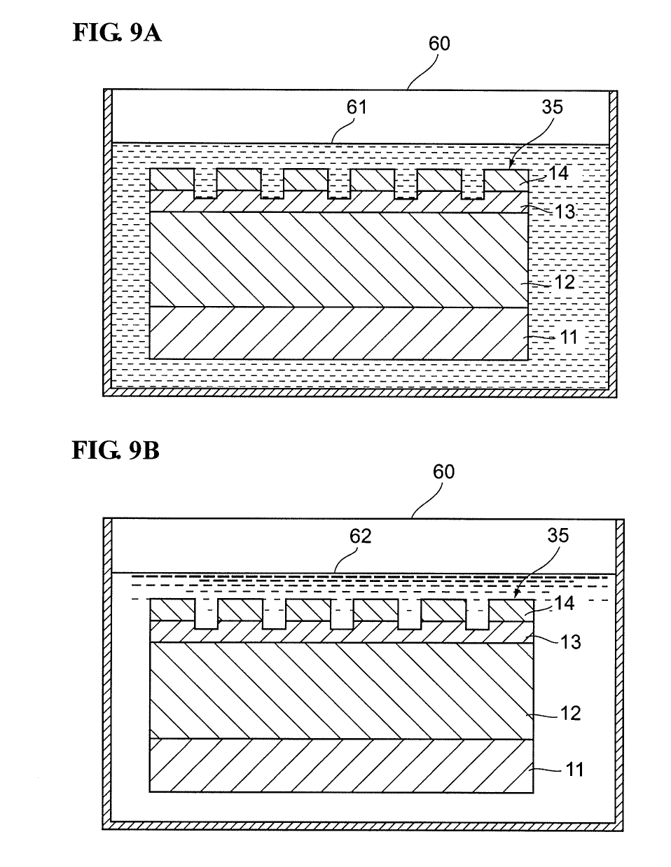

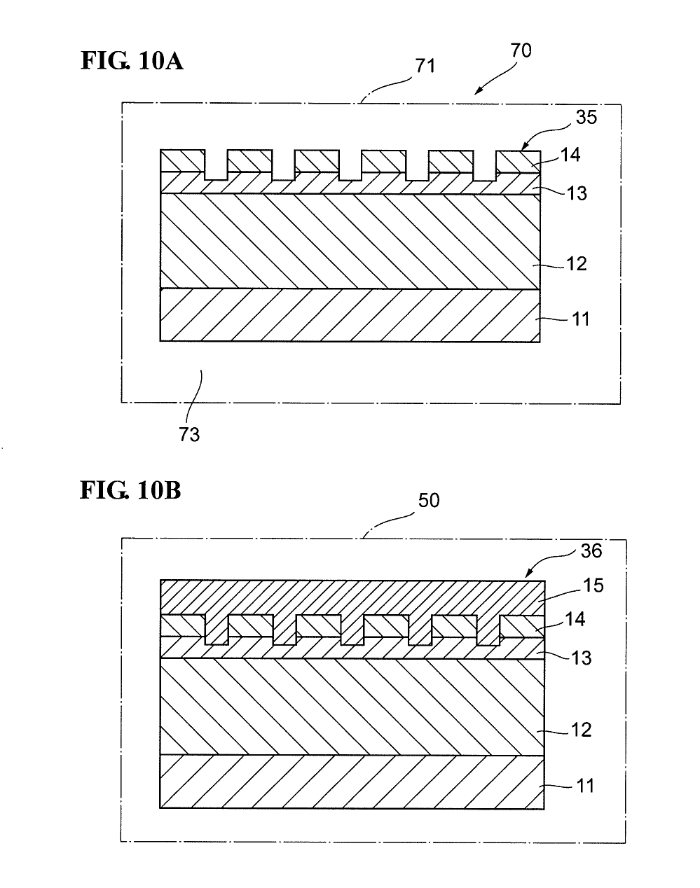

Next, a method of manufacturing a DFB laser including a process of cleaning a diffraction grating according to this embodiment will be described in detail with reference to FIGS. 5 and 9A to 10B. FIG. 5 is a flow chart showing a method of manufacturing a DFB laser according to this embodiment. FIGS. 9A to 10B are each a cross-sectional side view showing a substrate product produced by a process of the method of manufacturing a DFB laser according to this embodiment. FIGS. 5 and 9A to 10B describe in detail the step of forming a diffraction grating (S14) shown in FIG. 1.

As shown in FIG. 5, from the step of forming the insulating film 26 (S50) to the step of cleaning using ultrapure water 61 (S60), the method of manufacturing a DFB laser according to this embodiment is the same as the method of manufacturing a DFB laser using a process of cleaning a diffraction grating according to the comparative example described above. Consequently, description will be made on the step of cleaning using ultrapure water 61 and the subsequent steps.

### (First Step)

As shown in FIG. 9A, in order to clean off extraneous matter including hydrofluoric acid and the like adhering to the grating layer 14 provided with the diffraction grating, a substrate product 35 is placed in a cleaning apparatus 60 and then, the substrate product 35 is cleaned (S60). In the cleaning process, ultrapure water 61 is used as a cleaning liquid.

### (Second Step)

After the step of cleaning using ultrapure water 61 (S60), as shown in FIG. 9B, ultrapure water 61 is replaced with a water-soluble organic solvent 62 at room temperature (25° C.) (S61). The water-soluble organic solvent 62 has a temperature of 25° C. In addition, a water-soluble organic solvent 62 having high volatility is used. As the organic solvent 62, for example, an alcohol, such as isopropyl alcohol, methanol, or ethanol, is preferably used. In particular, isopropyl alcohol having high volatility is suitable. By immersing the substrate product 35 in the organic solvent 62 at room temperature for 5 minutes, ultrapure water 61 is replaced with the organic solvent 62. Next, as shown in FIG. 10A, the substrate product 35 is loaded in a drying apparatus 70. Before loading the substrate product 35 in the drying apparatus 70, an organic solvent 62 is placed in the liquid form in the drying apparatus 70. Then, by heating the organic solvent 62 placed inside the drying apparatus 70 to a temperature equal to or higher than the boiling point of the organic solvent 62, an atmosphere 73 containing the organic solvent 62 is generated. For example, when isopropyl alcohol is used as the organic solvent 62, isopropyl alcohol is heated up to a temperature equal to or higher than 84.2° C. which is the boiling point of isopropyl alcohol. Then, the surface of the substrate product 35 is exposed in the atmosphere 73 containing the water-soluble organic solvent 62. As a result, the organic solvent 62 in the form of liquid adhering to the surface of the substrate product 35 is dried off in the atmosphere 73 (S63). In addition, in order to prevent dissolution of the components of a container 71 due to heating, the container 71 of the drying apparatus 70 is preferably composed of quartz.

### (Third Step)

After drying the surface of the substrate product 35, as shown in FIG. 10B, the substrate product 35 is immediately loaded into a growth chamber 50, and part of a second cladding layer 15 is grown on the grating layer 14 (S64). Then, a substrate product 36 is formed. In this embodiment, the grating layer 14 is composed of p-type GaInAsP, and the second cladding layer 15 is composed of p-type InP. The band gap energy of GaInAsP constituting the grating layer 14 is smaller than the band gap energy of InP constituting the second cladding layer. Consequently, a heterojunction is formed at the regrowth interface between the grating layer 14 and the second cladding layer 15. At the heterojunction, a hetero-barrier due to a difference in band gap energy is present.

Regarding the method of manufacturing a semiconductor laser having a diffraction grating according to this embodiment, problems in the manufacturing method according to the comparative example will be described first, and then, the advantageous effects of the method of manufacturing a semiconductor laser having a diffraction grating according to this embodiment will be described.

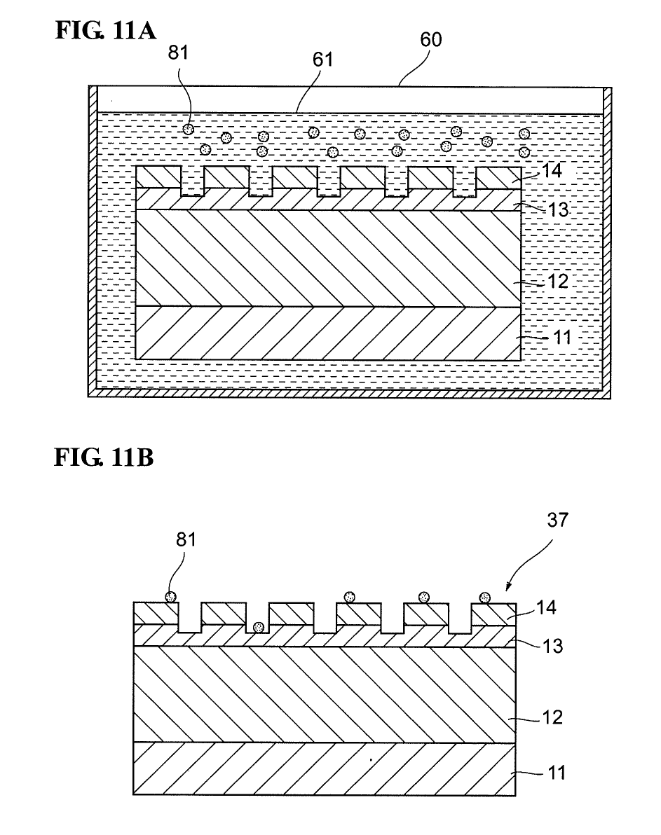

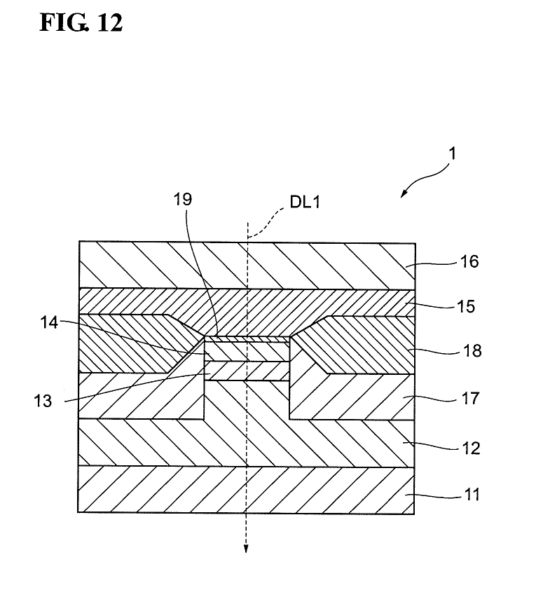

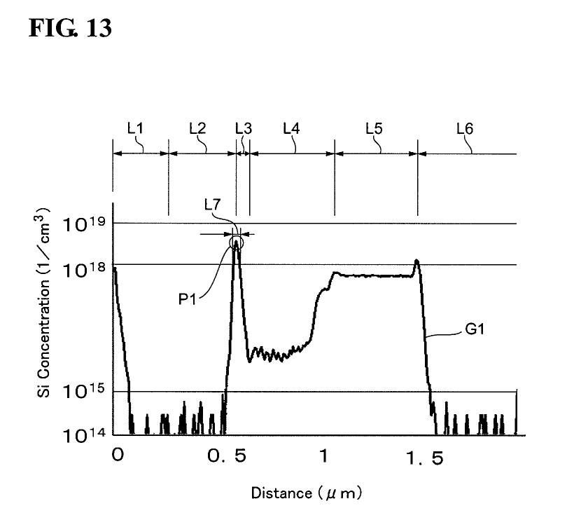

First, problems in the manufacturing method according to the comparative example will be described with reference to FIGS. 11A to 13. FIGS. 11A and 11B are cross-sectional views showing the reason why silicon 81 contained in ultrapure water 61 remains on the surface of a grating layer 14 provided with the projections and recesses. FIG. 12 is a cross-sectional view of a semiconductor laser 1 having a diffraction grating. In FIG. 12, a line DL1 shows the position at which the silicon concentration was measured inside the semiconductor laser 1. FIG. 13 is a graph showing the silicon concentration at the measurement position shown in FIG. 12. The silicon concentration is measured as the number of Si atoms per unit volume. Note that the silicon concentration was measured by secondary ion mass spectroscopy (SIMS). The semiconductor laser 1 having a diffraction grating is a DFB laser in this example.

The series resistance of a semiconductor laser having a diffraction grating affects the modulation characteristic. In the semiconductor laser having a diffraction grating produced by the manufacturing method according to the comparative example, the semiconductor laser has a relatively high series resistance due to the high concentration of silicon (Si) at the interface between the grating layer 14 and the second cladding layer 15. Increasing series resistance due to the high silicon concentration at the interface between the grating layer 14 and the second cladding layer 15 influences laser characteristics such as high modulation characteristics. Especially, when the semiconductor laser is directly modulated at a high modulation rate of 10 Gbps or more, the high-frequency characteristics of the semiconductor laser is remarkably degraded by having the high-resistivity layer. Therefore, it is necessary to decrease the series resistance of the semiconductor laser.

A semiconductor laser having a diffraction grating has a series resistance due to the specific resistance of materials. In addition, a high-resistivity layer formed at the interface between epitaxially grown layers is considered to be a component constituting the series resistance of a semiconductor laser having a diffraction grating. In order to avoid formation of a high-resistivity layer at the interface between epitaxially grown layers, very high cleanliness without residues is required at the interface. In the past, it has been thought that by cleaning the surface of the grating layer 14 provided with periodic projections and recesses with ultrapure water 61, and then regrowing the second cladding layer 15 on the grating layer 14, a clean growth interface can be obtained.

However, for example, as shown in FIG. 11A, ultrapure water 61 contains several parts per billion of silicon 81. After the surface of the grating layer 14 is cleaned with ultrapure water 61, the substrate product 37 is taken out from the cleaning apparatus 60, and ultrapure water 61 adhering to the surface of the grating layer 14 is dried off. In this process, as shown in FIG. 11B, silicon 81 contained in ultrapure water 61 accumulates at the regrowth interface of the substrate product 37. In general, in a method of producing ultrapure water 61, such as an ion-exchange resin method, it is difficult to decrease the content of the silicon 81 in ultrapure water 61 to several parts per billion or less. Consequently, it is difficult to completely reduce the amount of silicon 81 accumulated at the regrowth interface to zero.

Furthermore, in the manufacturing method according to the comparative example, in order to perform drying after cleaning with ultrapure water 61, for example, a method of drying using a spin dryer or a method of drying by nitrogen blowing is employed. In these methods, ultrapure water 61 adhering to the surface of the grating layer 14 provided with the projections and recesses is not dried off uniformly, resulting in occurrence of drying non-uniformly. Specifically, water droplets remain like scattered drops on the surface of the grating layer 14 provided with the projections and recesses, and drying proceeds with the water droplets gradually becoming smaller. In such a case, silicon 81 accumulates locally and remains on the surface of the grating layer 14 provided with the projections and recesses.

Silicon 81 is a stable material in the air. Therefore, it has been considered that, even if a minute amount of silicon is contained in the residue on the regrowth interface, the performance of the semiconductor laser having a diffraction grating will not be affected.

However, it has become clear that, the residual silicon on the regrowth interface affects the performance of the semiconductor laser having a diffraction grating. Silicon 81 remaining on the regrowth interface works as an n-type dopant. When at least one of the first semiconductor layer and the second semiconductor layer constituting the regrowth interface is a p-type semiconductor doped with, for example, zinc (Zn), silicon 81 remaining on the regrowth interface, compensates the p-type semiconductor. That is, zinc, which is an impurity of the p-type semiconductor, diffuses and is trapped by silicon 81, and complex bonds are formed between silicon and zinc. As a result, zinc is inactivated and a high-resistivity layer is formed in a region where silicon remains. Consequently, when at least one of the first semiconductor layer and the second semiconductor layer constituting the regrowth interface is a p-type semiconductor, a high-resistivity layer is formed on the regrowth interface because silicon 81 compensates the p-type semiconductor. Increasing a series resistance due to the high-resistivity layer degrades high-frequency response characteristics of the semiconductor laser, especially at a high-speed modulation rate of 10 Gbps or more. In addition, when the first semiconductor layer and the second semiconductor layer constituting the regrowth interface are composed of different semiconductor materials, a heterojunction is formed at the regrowth interface. Consequently, the hetero-barrier at the heterojunction increases the resistance of the high-resistivity layer, resulting in further degradation in the high-frequency response characteristics of the semiconductor laser.

Next, the silicon depth profile of a semiconductor laser 1 having a diffraction grating as shown in FIG. 12 will be described. The silicon concentration was measured along the broken line DL1 extending from the contact layer 16 toward the semiconductor substrate 11, using SIMS. In this case, a high-resistivity layer caused by residual silicon 81 is formed in a region 19 in the vicinity of the regrowth interface formed between the grating layer 14 composed of p-type InGaAsP and the second cladding layer 15 composed of p-type InP.

FIG. 13 is a graph showing the silicon concentration in a direction along the broken line DL1 of FIG. 12. In FIG. 13, the vertical axis shows the silicon concentration, and the horizontal axis shows the distance from the surface of the contact layer 16 in the direction along the broken line DL1 of FIG. 12. G1 indicates the silicon concentration in the direction along the broken line DL1. L1 indicates the corresponding region to the contact layer 16 composed of p-type InGaAs. L2 indicates the corresponding region to the second cladding layer 15 composed of p-type InP. L3 indicates the corresponding region to the grating layer 14 composed of p-type InGaAsP. L4 indicates the corresponding region to the active layer 13 having a multiple quantum well structure. L5 indicates the corresponding region to the first cladding layer 12 composed of n-type InP. L6 indicates the corresponding region to the semiconductor substrate 11 composed of Sn-doped n-type InP. Furthermore, L7 indicates the corresponding region to the region 19 where the high-resistivity layer is formed. The regrowth interface is present in the region 19. Referring to FIG. 13, a region having a high silicon concentration is formed in the range of L7. The peak value P1 of the silicon concentration is 3.83×10¹⁸ (1/cm³).

Next, the advantageous effects of the method of manufacturing a semiconductor laser having a diffraction grating according to this embodiment will be described. Silicon 81 accumulates at the regrowth interface in the process of drying off water adhering to the surface of the first semiconductor layer (grating layer 14) after cleaning with water (ultrapure water 61). In the method of manufacturing a semiconductor laser having a diffraction grating according to this embodiment, water used for cleaning the surface of the first semiconductor layer having the projections and recesses is replaced with the water-soluble organic solvent 62. Then, by exposing the surface of the first semiconductor layer in the atmosphere 73 containing the water-soluble organic solvent 62, the water-soluble organic solvent 62 in the liquid form adhering to the surface of the first semiconductor layer having the projections and recesses is dried off. In such a manner, by drying off the water-soluble organic solvent 62 after water used for cleaning has been replaced with the water-soluble organic solvent 62, the residual silicon concentration at the surface of the first semiconductor layer can be decreased. By forming the second semiconductor layer (second cladding layer 15) on the surface of the first semiconductor layer in which the residual silicon concentration has been decreased, it is possible to form a regrowth interface with a decreased residual silicon concentration. By decreasing the residual silicon concentration at the regrowth interface, even when at least one of the first semiconductor layer and the second semiconductor layer constituting the regrowth interface is a p-type semiconductor, it is possible to suppress the formation of a high-resistivity layer caused by residual silicon. Therefore, the series resistance of the semiconductor laser having a diffraction grating is decreased. Consequently, it is possible to manufacture a semiconductor laser having a diffraction grating and having high-speed modulation characteristics. In particular, when the first semiconductor layer and the second semiconductor layer constituting the regrowth interface are semiconductor layers composed of different materials and a heterojunction is formed at the regrowth interface, it is possible to obtain a large effect of suppressing the formation of a high-resistivity layer or a large effect of decreasing the resistance of the high-resistivity layer. These suppressing the formation of a high-resistivity layer or decreasing the resistance of the high-resistivity layer is realized by decreasing the residual silicon concentration at the regrowth interface for the semiconductor laser having a diffraction grating. In such a manner, in the semiconductor laser in which the first semiconductor layer and the second semiconductor layer are composed of different materials, by using the method of manufacturing a semiconductor laser having a diffraction grating according to this embodiment, it is also possible to effectively decrease the series resistance of the semiconductor laser having a diffraction grating. Consequently, it is possible to manufacture a semiconductor laser having a diffraction grating and having good modulation characteristics.

Furthermore, preferably, the semiconductor substrate 11 contains an n-type semiconductor. In this case, a semiconductor laser includes a semiconductor substrate 11 composed of an n-type semiconductor, a first cladding layer 12 composed of an n-type semiconductor, an active layer 13, a grading layer 14 composed of a p-type semiconductor, and a second cladding layer 15 composed of a p-type semiconductor. Therefore, the grating layer 14 and the second cladding layer 15 constituting the regrowth interface are each composed of a p-type semiconductor. Therefore, the manufacturing method according to the present invention can be suitably applied thereto.

Furthermore, preferably, the organic solvent 62 is at least one of isopropyl alcohol, methanol, and ethanol. Isopropyl alcohol, methanol, and ethanol have high volatility and can be quickly dried off.

### EXAMPLE 1

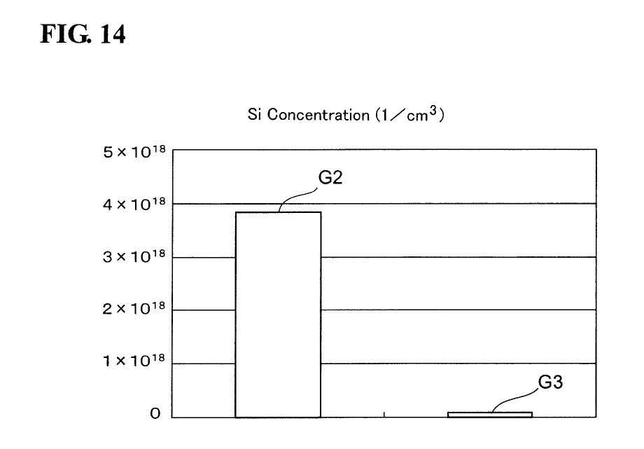

In Example 1, a first semiconductor laser was produced using the manufacturing method according to the comparative example, and a second semiconductor laser was produced using the manufacturing method according to this embodiment. Next, the silicon concentration at the regrowth interface of each semiconductor laser was measured using a secondary ion mass spectrometer (SIMS). FIG. 14 is a graph showing the measurement result of the silicon concentration at the regrowth interface of the first semiconductor laser and the measurement result of the silicon concentration at the regrowth interface of the second semiconductor laser. G2 indicates the silicon concentration at the regrowth interface of the first semiconductor laser, and G3 indicates the silicon concentration at the regrowth interface of the second semiconductor laser.

As shown in FIG. 14, the silicon concentration at the regrowth interface of the first semiconductor laser is 3.83×10¹⁸ (1/cm³), and the silicon concentration at the regrowth interface of the second semiconductor laser is 9.00×10¹⁶ (1/cm³). Consequently, it is clear that by using the manufacturing method according to this embodiment, the residual silicon concentration at the regrowth interface can be decreased to about one-fortieth.

### EXAMPLE 2

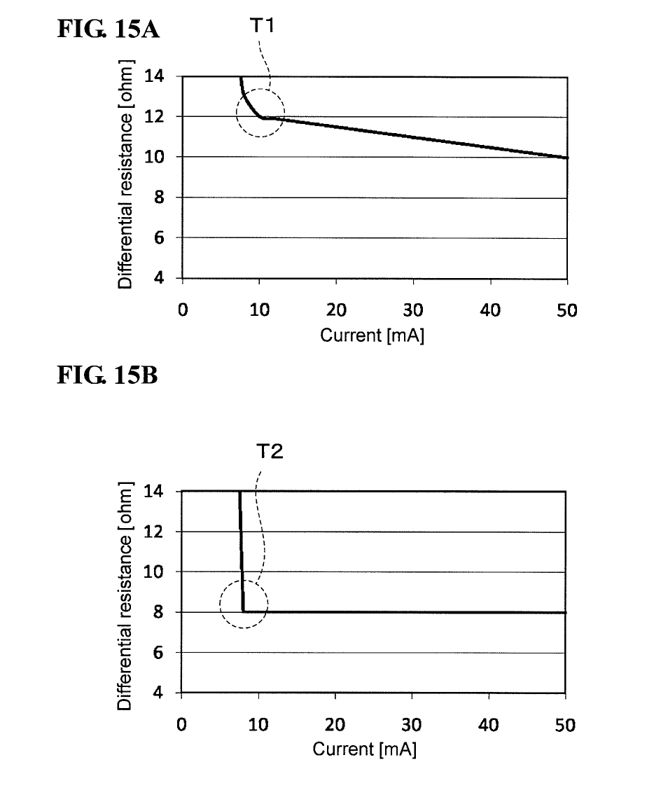

Next, the relationship between current and differential resistance, which is one of the semiconductor laser characteristics, was measured on the first semiconductor laser and the second semiconductor laser produced in Example 1. FIG. 15A and 15B are graphs showing the relationship between current and differential resistance for the first and second semiconductor lasers, respectively. It is clear that, in the first semiconductor laser, the differential resistance T1 in the vicinity of the threshold current is 12 ohm. The threshold current of the first semiconductor laser is about 10 mA in FIG. 15A. This differential resistance T1 can become a factor for degrading the high-speed modulation characteristic, especially at a high modulation rate of more than 10 Gbps. In contrast, it is clear that, in the second semiconductor laser, the differential resistance T2 in the vicinity of the threshold is 8 ohm. The threshold current of the second semiconductor laser is about 8 mA in FIG. 15B. The reason for this is believed to be that the silicon concentration at the regrowth interface of the diffraction grating in the second semiconductor laser is smaller than that in the first semiconductor laser. Consequently, by using the method shown in this embodiment, the differential resistance in the vicinity of the threshold current can be decreased from 12 ohm to 8 ohm. Thus, the high-speed modulation characteristics can be improved.

### EXAMPLE 3

Next, the signal fall time, which is one of the semiconductor laser characteristics, was measured on the first semiconductor laser and the second semiconductor laser produced in Example 1. In the first semiconductor laser, the fall time was 41 picoseconds. In contrast, in the second semiconductor laser, the fall time was 36 picoseconds. The results show that the high-speed modulation performance is improved.

Principles of the present invention have been described on the basis of preferred embodiments with reference to the drawings. However, those skilled in the art will understand that the embodiments can be changed in terms of details without departing from the principles. Therefore, all the modifications and changes within the scope and the spirit of Claims are claimed as the present invention.

What is claimed is:

1. A method of manufacturing a semiconductor laser having a diffraction grating, the method comprising the steps of:
forming a first semiconductor layer on a semiconductor substrate;
forming periodic projections and recesses which constitute a diffraction grating in the first semiconductor layer;
cleaning a surface of the first semiconductor layer provided with the projections and recesses with water;
drying the surface of the first semiconductor layer provided with the projections and recesses; and
forming a second semiconductor layer on the first semiconductor layer provided with the projections and recesses,
wherein in the step of drying the surface of the first semiconductor layer provided with the projections and recesses, after replacing water adhering to the surface of the first semiconductor layer with a water-soluble organic solvent, the surface of the first semiconductor layer provided with the projections and recesses is exposed in an atmosphere containing the water-soluble organic solvent; and
at least one of the first semiconductor layer and the second semiconductor layer is composed of a p-type semiconductor.

2. The method of manufacturing a semiconductor laser having a diffraction grating according to claim 1, wherein in the step of drying the surface of the first semiconductor layer provided with the projections and recesses, in replacing water adhering to the surface of the first semiconductor layer with the water-soluble organic solvent, the semiconductor substrate is immersed in the water-soluble organic solvent at room temperature after the step of cleaning the surface of the first semiconductor layer with water; and
in exposing the surface of the first semiconductor layer provided with the projections and recesses in an atmosphere containing the water-soluble organic solvent, the atmosphere containing the water-soluble organic solvent is generated by heating the water-soluble organic solvent to a temperature equal to or higher than the boiling point of the water-soluble organic solvent.

3. The method of manufacturing a semiconductor laser having a diffraction grating according to claim 1, wherein the semiconductor substrate is composed of an n-type semiconductor.

4. The method of manufacturing a semiconductor laser having a diffraction grating according to claim 1, wherein the first semiconductor layer and the second semiconductor layer are composed of different semiconductors;
the band gap energy of the first semiconductor layer is different from the band gap energy of the second semiconductor layer; and
in the step of forming the second semiconductor layer on the first semiconductor layer, a heterojunction is formed at the interface between the first semiconductor layer and the second semiconductor layer.

5. The method of manufacturing a semiconductor laser having a diffraction grating according to claim 1, wherein the water-soluble organic solvent is at least one of isopropyl alcohol, methanol, and ethanol.

6. The method of manufacturing a semiconductor laser having a diffraction grating according to claim 1, wherein the first semiconductor layer is composed of p-type GaInAsP, and the second semiconductor layer is composed of p-type InP.
